(19) United States
(12) Patent Application Publication
(10) Pub. No.: US 2014/0288861 A1
(43) Pub. Date: Sep. 25, 2014

(54) SAMPLING METHODOLOGY FOR MEASURING POWER CONSUMPTION FOR A POPULATION OF POWER-CONSUMING DEVICES

(71) Applicant: XEROX CORPORATION, Norwalk, CT (US)

(72) Inventors: Eric Michael Gross, Rochester, NY (US); Lina Fu, Fairport, NY (US); Shu Chang, Pittsford, NY (US); William Kenneth Stumbo, Fairport, NY (US); Fritz Francis Ebner, Pittsford, NY (US)

(73) Assignee: Xerox Corporation, Norwalk, CT (US)

(21) Appl. No.: 13/847,642

(22) Filed: Mar. 20, 2013

(51) Int. Cl. G01R 21/133

(52) U.S. Cl. CPC G01R 21/133
USPC 702/60

(57) ABSTRACT

A method and device for performing a sampling methodology for measuring power consumption for a population of power-consuming devices. The device includes a processor configured to perform the method. The method includes determining an energy consumption level for each device in a population of power-consuming devices; clustering the population of power-consuming devices into a plurality of clusters such that each of the plurality of clusters has a similar overall energy consumption; determining an estimated total energy consumption for each cluster; determining an estimated total energy consumed by the population of devices based upon the total energy consumption for each cluster, wherein the estimated total energy consumed by the population is within an acceptable uncertainty; and determining a number of samples to measure in each cluster such that the uncertainty associated with the estimated total energy consumed by the population of devices is minimized.

### BACKGROUND

The present disclosure relates to measuring energy consumption. More specifically, the present disclosure relates to measuring energy consumption across a large number of devices.

Energy consumption reporting and control for a power-consuming device, such as a computer, printer, or other item of office equipment, is becoming more interesting to consumers. As electricity becomes more expensive, and consumers strive to become more environmentally conscious, accurate power consumption and modeling is becoming more important. Additionally, many states and utility providers provide rebates or tax credits for using energy efficient devices.

Typically, energy consumption for a large number of devices is estimated using Energy Star® estimates or other broad measures of energy usage measuring. Measuring the energy usage at each individual device grouped into a large collection of devices is often an inefficient use of time and a large expense.

Some companies may manage thousands of devices located at a variety of sites. In such environments, collecting, interpreting, analyzing and reporting energy usage statistics for each individual device is thus impractical, and typical energy usage estimate techniques may be too broad to provide an accurate measurement of energy usage for reporting to state or other utility providers or regulators for potential rebates or tax credits.

### SUMMARY

In one general respect, the embodiments disclose a method including determining an energy consumption level for each device in a population of power-consuming devices; clustering the population of power-consuming devices into a plurality of clusters such that each of the plurality of clusters has a similar overall energy consumption; determining an estimated total energy consumption for each cluster; determining an estimated total energy consumed by the population of devices based upon the total energy consumption for each cluster, wherein the estimated total energy consumed by the population is within an acceptable uncertainty; and determining a number of samples to measure in each cluster such that the uncertainty associated with the estimated total energy consumed by the population of devices is minimized.

In another general respect, the embodiments disclose device including a processor and a non-transitory computer readable medium operably connected to the processor. The computer readable medium contains a set of instructions configured to instruct the processor to determine an energy consumption level for each device in a population of power-consuming devices; cluster the population of power-consuming devices into a plurality of clusters such that each of the plurality of clusters has a similar overall energy consumption; determine an estimated total energy consumption for each cluster; determine an estimated total energy consumed by the population of devices based upon the total energy consumption for each cluster, wherein the estimated total energy consumed by the population is within an acceptable uncertainty; and determine a number of samples to measure in each cluster such that the uncertainty associated with the estimated total energy consumed by the population of devices is minimized.

In another general respect, the embodiments disclose a method including determining an energy consumption level for each multi-function printing device in a population of multi-function printing devices based upon the power model for an associated multi-function printing device and usage statistics for the associated multi-function printing device; clustering the population of power-consuming devices into a plurality of clusters such that each of the plurality of clusters has a similar overall energy consumption; determining an estimated total energy consumption for each cluster; determining an estimated total energy consumed by the population of multi-function printing devices based upon the total energy consumption for each cluster, wherein the estimated total energy consumed by the population is within an acceptable uncertainty; and determining a number of samples to measure in each cluster such that the uncertainty associated with the estimated total energy consumed by the population of multi-function printing devices is minimized.

### BRIEF DESCRIPTION OF THE DRAWINGS

FIG. 1 depicts an organized view of a population of devices according to an embodiment.

FIG. 2 depicts a set of distributions for multiple device clusters according to an embodiment.

FIG. 3 depicts a sample flow diagram of a process for identifying a number of measurement devices to use in each cluster for a population according to an embodiment.

FIG. 4 depicts various embodiments of a computing device for implementing the various methods and processes described herein.

### DETAILED DESCRIPTION

This disclosure is not limited to the particular systems, devices and methods described, as these may vary. The terminology used in the description is for the purpose of describing the particular versions or embodiments only, and is not intended to limit the scope.

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. Nothing in this disclosure is to be construed as an admission that the embodiments described in this disclosure are not entitled to antedate such disclosure by virtue of prior invention. As used in this document, the term “comprising” means “including, but not limited to.”

As used herein, a “device” refers to an electronic device that consumes power from one or more power sources and that is configured to perform one or more specific functions. Each device has an associated power model that defines the device's power consumption during certain states as well as the device's power consumption during transitions between certain states.

A “computing device” or “processing device” refers to a device that processes data in order to perform one or more functions. A computing device may include any processor-based device such as, for example, a server, a personal computer, a personal digital assistant, a web-enabled phone, a smart terminal, a dumb terminal and/or other electronic device capable of communicating in a networked environment. A computing device may interpret and execute instructions.

A common and fundamental problem in statistics is to determine a sampling strategy to improve the likelihood of obtaining reasonable estimates of population parameters. Since sampling is often costly, there is a point at which improved accuracy in estimating a population parameter is offset by the economic cost of obtaining information. In such situations, it is important to sample intelligently so as to maximize the information obtained with respect to the cost expended. In a situation in which there is a large population, and there is reason to believe that there are subpopulations that are more or less homogeneous, then a method of stratified sampling can be a sensible approach. Stratified sampling strategies have traditionally relied on approaches that allocate samples in proportion to the ratio of the subpopulation to that of the total population, or allocating samples in proportion to the standard deviations of the subpopulations.

The present disclosure is directed to a method and device for providing an optimal stratified sampling model. The model is used to divide a population of devices and identify subpopulations, or clusters, of devices that are relatively homogeneous. A numerical method is then applied to identify a number of clusters, and the number of samples to obtain from each cluster, so as to minimize the variance of the overall estimated population mean. The model may be used to increase the efficiency of monitoring for companies tasked with accurately estimating and reporting the energy consumption of a large number of devices.

More specifically, as described herein, model based energy consumption data provides an estimate of clusters of “similar” devices, when considering energy consumption. Each cluster may then be sampled to estimate the true cluster means. Based upon the number of measurement devices available for the entire population, the optimal number of measurement devices to include in each cluster may be determined such that the precision of the total energy consumption estimate is maximized. It should be noted that, as used herein, the term mean refers to any mathematical operation in which multiple data inputs are summarized in a smaller number of data outputs.

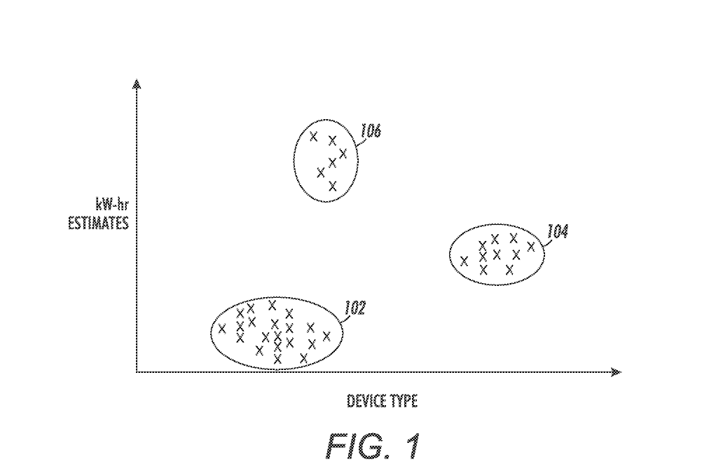

FIG. 1 illustrates an organized log of various devices contained within a sample population. The x-axis of the log indicates device type, and the y-axis indicates kilowatt hour estimates. Each device within the population is organized within the log according to device type and estimated energy consumption levels. As shown in FIG. 1, clusters of devices may be identified. For example, these may be clusters of printers in an office environment, clusters of computers or monitors in a school facility, clusters of lighting fixtures in a retail facility, a combination of energy-consuming devices located in multiple locations, or other such device groups.

During clustering, each device may be assigned to a specific cluster based upon that device's associated energy consumption level. In order to provide a high precision estimate of the number of measurement devices to use for each cluster, division of the devices into clusters should occur such that each cluster may have a similar overall energy usage as the other clusters. Similar may mean, for example, no more than a 1% difference in energy consumption, no more than a 3% difference in energy consumption, no more than a 5% difference in energy consumption, or no more than 10% difference in energy consumption. Thus, when creating clusters, a larger number of low energy devices may be clustered together, as shown in cluster 102, while a smaller number of higher energy devices may be clustered together, as is shown in clusters 104 and 106. As a result, each individual cluster 102, 104 and 106, while having varying numbers of individual devices, has a similar overall energy consumption.

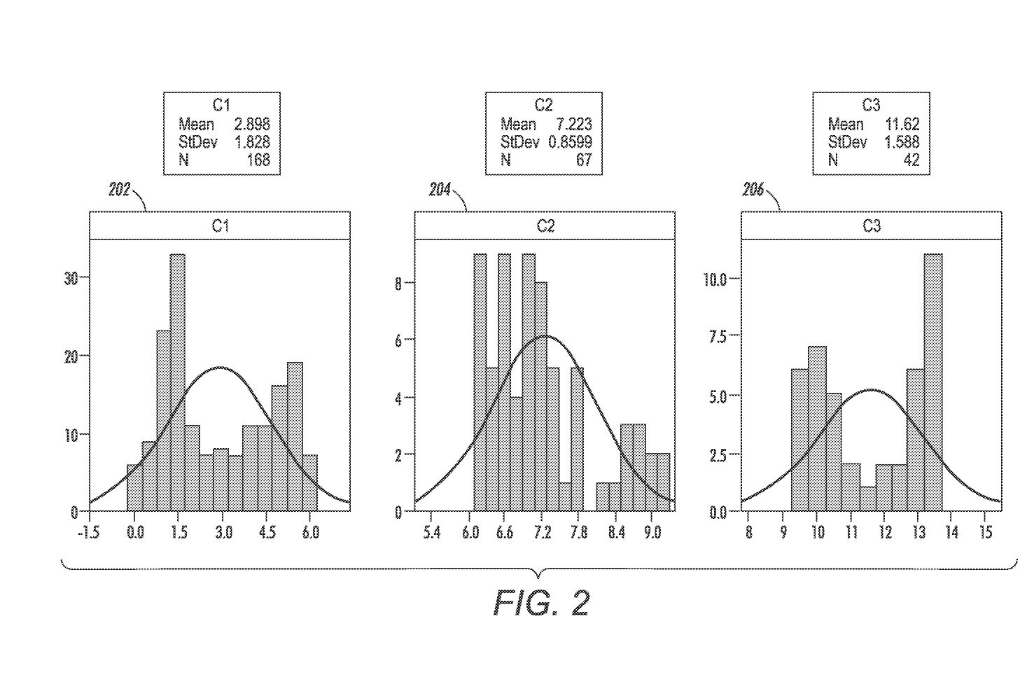

FIG. 2 illustrates a set of distributions 202, 204 and 206 for a set of three clusters. It should be noted that in the present disclosure, there is no assumption that the distributions are normal, or are of any other specific form. Additional information, such as the mean energy consumption per device in each cluster, the standard deviation of the distribution for each cluster, and the number of devices in each cluster may be provided as well. It should also be noted that the information related to each distribution 202, 204 and 206 as shown in FIG. 2 is provided by way of example only.

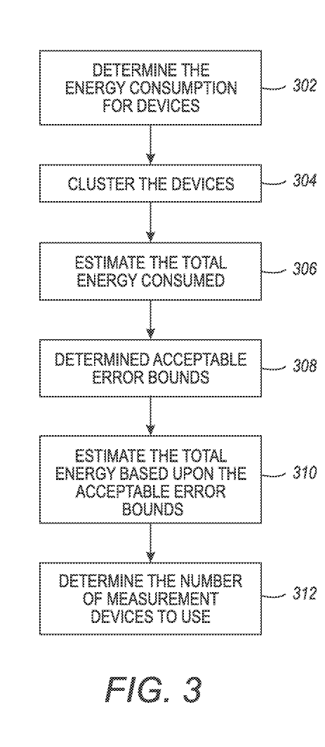

In order to accurately measure the power consumption amongst the devices in the population, while still maintaining a high precision and reducing the overall cost, a limited number of measurement devices should be allocated among the clusters to get high quality estimates of mean energy consumption of each cluster. FIG. 3 illustrates a sample process for determining how many measurement devices should be allocated to each cluster. A processing device may identify a population of devices and determine 302 the estimated energy consumption for each device. The estimated energy consumption may be determined 302 by reviewing a power model associated with the device as supplied by the device's manufacturer and/or created by a user or monitoring system along with usage statistics, or anticipated usage statistics, associated with the device.

The processing device may cluster 304 the devices, similar to the description of clustering provided above in regard to FIG. 1. As described above, clustering 304 is performed to such that each cluster is similar in overall energy consumption. In this example, a population has been divided into six clusters. However, it should be noted this division is for purposes of example only, and more or less clusters may be used as appropriate.

Once the devices are clustered 304, the processing device may estimate the total energy consumed by the entire population. To calculate the exact total energy, the following equation may be used:

E_{Total}=N₁η₁+N₂η₂+N₃η₃+N₄η₄+N₅η₅+N₆η₆

where Nᵢ is the number of devices in cluster i, and ηᵢ is the true average for energy consumption within cluster i. However, since the true average is not known, an average energy per cluster Ēᵢ may be used. Thus, the following equation may be used to estimate the total energy in all clusters:

E_{Total}≈N₁Ē₁+N₂Ē₂+N₃Ē₃+N₄Ē₄+N₅Ē₅+N₆Ē₆

Additionally, Ēᵢ, being the average of ηᵢ measurement, is more nearly normal (e.g., the larger the number ηᵢ, the better the normal approximation) when calculating cluster deviation.

Depending on the application of the energy estimation being calculated, the processing device may determine 308 acceptable error bounds. Alternatively, a user or administrator may set the level of acceptable error bounds for the estimation calculations. In this example, it is assumed that a normal approximation is adequate and so Ēᵢ is within the true means by

$$η \pm \frac{{σ}_{i}}{\sqrt{{n}_{i}}} ,$$

with approximate 68% probability.

It should be noted that, in this example, the actual standard deviation σᵢ of each cluster is unknown since this methodology uses power device models to obtain an initial estimate of power consumption. The methodology therefore uses the model based standard deviation. Thus, the processing device may estimate 310 the total energy, with the 68% error bounds, using the following equation:

$${E}_{Total} \approx {N}_{1} \cdot ( {\overline{E}}_{1} \pm \frac{{\hat{σ}}_{1}}{\sqrt{{n}_{1}}} ) + {N}_{2} \cdot ( {\overline{E}}_{2} \pm \frac{{\hat{σ}}_{2}}{\sqrt{{n}_{2 }}} ) + {N}_{3} \cdot ( {\overline{E}}_{3} \pm \frac{{\hat{σ}}_{3}}{\sqrt{{n}_{3}}} ) + {N}_{4} \cdot ( {\overline{E}}_{4} \pm \frac{{\hat{σ}}_{4}}{\sqrt{{n}_{4}}} ) + {N}_{5} \cdot ( {\overline{E}}_{5} \pm \frac{{\hat{σ}}_{5}}{\sqrt{{n}_{5}}} ) + {N}_{6} \cdot ( {\overline{E}}_{6} \pm \frac{{\hat{σ}}_{5}}{\sqrt{{n}_{6}}} )$$

For example, in a population where the average is estimated, the true average will be within 1 standard deviation of the estimated average 68% of the time, within two standard deviations 95% of the time, within three standard deviations 99% of the time, and so on.

The processing device may then use the estimated 310 total energy to determine 312 a number of measurement devices K to use in each cluster. It should be noted there may be several constraints used to define K . For example, 0≦K≦Kₘₐₓ where Kₘₐₓ is the maximum number of measurement devices allocated for a specific population. Additionally, n₁+n₂+n₃+n₄+n₅+n₆=K where nᵢ is the number of measurement devices allocated for cluster i.

Thus, to determine 312 the number of measurement device to use for each cluster, the task becomes how to allocate n₁, n₂, n₃, n₄, n₅ and n₆ to minimize the uncertainty associated with E_{Total} such that the overall uncertainty associated with E_{Total} is within an acceptable uncertainty range. As this is the sum of a set of random variables, the problem statement becomes how to determine the integers, the following equation may be used:

$$J = \frac{{( {N}_{1} {\hat{σ}}_{1} )}^{2}}{{n}_{1}} + \frac{{( {N}_{2} {\hat{σ}}_{2} )}^{2}}{{n}_{2}} + \frac{{( {N}_{3} {\hat{σ}}_{3} )}^{2}}{{n}_{3}} + \frac{{( {N}_{4} {\hat{σ}}_{4} )}^{2}}{{n}_{4}} + \frac{{( {N}_{5} {\hat{σ}}_{5} )}^{2}}{{n}_{5}} + \frac{{( {N}_{6} {\hat{σ}}_{6} )}^{2}}{{n}_{6}}$$

subject to the constraint that n₁+n₂+n₃+n₄+n₅+n₆=K. Thus, referring back to the equation for calculating E_{Total}, and based upon the values for \hat{σ}₁, \hat{σ}₂, \hat{σ}₃, \hat{σ}₄, \hat{σ}₅ and \hat{σ}₆, one can determine approximately how many measuring device should be allocated to each cluster.

For example, if \hat{σ}₁ is considerably larger than each of the other values, then a larger percentage of measuring devices should be allocated to cluster 1 as compared to the other clusters.

It should be noted that J, the variance of the sum E_{Total}, holds approximate since the distributions for each cluster are finite. Additionally, it should be noted that, as used herein, the terms minimum and maximum should be construed broadly, with reference to a practical solution that may change over time, and should not be construed to require a mathematically proven minimum or maximum.

For example, to determine the integers n₁, n₂, n₃, n₄, n₅ and n₆, a basic exhaustive but efficient counting search may be conducted. A counting search operates by counting the number of objects that have a distinct key value, and using a specific algorithm on those counts to determine the positions of each key value in the output sequence. Provided only those integers in conformance with the constraints are evaluated, the computational complexity scales efficiently as well (the number of computations is bounded by the square of the arithmetic sum with difference 1). Additionally, starting near values that are proportional to the numerator terms are generally close, though not identical, to the optimal values.

It should be noted that the equations as included herein are shown by way of example only, and additional statistical analysis and estimation techniques may be incorporated as appropriate.

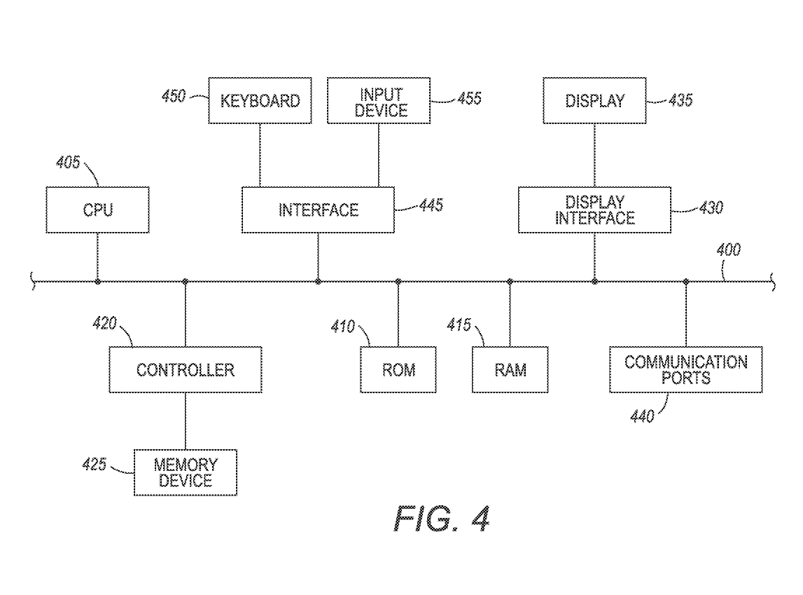

FIG. 4 depicts a block diagram of internal hardware that may be used to contain or implement the various computer processes and systems as discussed above. An electrical bus 400 serves as the main information highway interconnecting the other illustrated components of the hardware. CPU 405 is the central processing unit of the system, performing calculations and logic operations required to execute a program. For example, CPU 405 may perform the functions performed by the processing device in the above discussion of FIG. 3. CPU 405, alone or in conjunction with one or more of the other elements disclosed in FIG. 4, is a processing device, computing device or processor as such terms are used within this disclosure. Read only memory (ROM) 410 and random access memory (RAM) 415 constitute examples of memory devices.

A controller 420 interfaces with one or more optional memory devices 425 to the system bus 400. These memory devices 425 may include, for example, an external or internal DVD drive, a CD ROM drive, a hard drive, flash memory, a USB drive or the like. As indicated previously, these various drives and controllers are optional devices. Additionally, the memory devices 425 may be configured to include individual files for storing any software modules or instructions, auxiliary data, incident data, common files for storing groups of contingency tables and/or regression models, or one or more databases for storing the information as discussed above.

Program instructions, software or interactive modules for performing any of the functional steps associated with the processes as described above may be stored in the ROM 410 and/or the RAM 415. Optionally, the program instructions may be stored on a tangible computer readable medium such as a compact disk, a digital disk, flash memory, a memory card, a USB drive, an optical disc storage medium, such as a Blu-ray™ disc, and/or other recording medium.

An optional display interface 430 may permit information from the bus 400 to be displayed on the display 435 in audio, visual, graphic or alphanumeric format. Communication with external devices may occur using various communication ports 440. A communication port 440 may be attached to a communications network, such as the Internet or a local area network.

The hardware may also include an interface 445 which allows for receipt of data from input devices such as a keyboard 450 or other input device 455 such as a mouse, a joystick, a touch screen, a remote control, a pointing device, a video input device and/or an audio input device.

It will be appreciated that various of the above-disclosed and other features and functions, or alternatives thereof, may be desirably combined into many other different systems or applications or combinations of systems and applications. Also that various presently unforeseen or unanticipated alternatives, modifications, variations or improvements therein may be subsequently made by those skilled in the art which are also intended to be encompassed by the following claims.

What is claimed is:

1. A method comprising:
determining, by a processing device, an energy consumption level for each device in a population of power-consuming devices;
clustering, by the processing device, the population of power-consuming devices into a plurality of clusters such that each of the plurality of clusters has a similar overall energy consumption;
determining, by the processing device, an estimated total energy consumption for each cluster;
determining, by the processing device, an estimated total energy consumed by the population of devices based upon the total energy consumption for each cluster, wherein the estimated total energy consumed by the population is within an acceptable uncertainty; and
determining, by the processing device, a number of samples to measure in each cluster such that the uncertainty associated with the estimated total energy consumed by the population of devices is minimized.

2. The method of claim 1, wherein determining the energy consumption level for each device comprises determining an estimated power consumption for an associated device based upon a power model for the associated device and usage statistics for the associated device.

3. The method of claim 1, wherein clustering the population of devices further comprises:
organizing the population of devices based upon energy consumption levels; and
assigning each of the populations of devices into one of the plurality of clusters based upon similar energy consumption levels.

4. The method of claim 3, wherein a number of devices assigned to each cluster is determined such that a the estimated total energy consumption for each cluster is approximately equal.

5. The method of claim 1, wherein determining a number of samples to measure in each cluster comprises performing a counting search to determine the number of samples.

6. The method of claim 1, wherein determining the estimated total energy consumption for each cluster comprises:
determining a mean energy consumption for each cluster; and
multiplying the mean energy consumption for each cluster by the number of power consuming devices in that cluster.

7. A device comprising:
a processor; and
a non-transitory computer readable medium operably connected to the processor, the computer readable medium containing a set of instructions configured to instruct the processor to:
determine an energy consumption level for each device in a population of power-consuming devices,
cluster the population of power-consuming devices into a plurality of clusters such that each of the plurality of clusters has a similar overall energy consumption,
determine an estimated total energy consumption for each cluster,
determine an estimated total energy consumed by the population of devices based upon the total energy consumption for each cluster, wherein the estimated total energy consumed by the population is within an acceptable uncertainty, and
determine a number of samples to measure in each cluster such that the uncertainty associated with the estimated total energy consumed by the population of devices is minimized.

8. The device of claim 7, wherein the instructions for determining the energy consumption level for each device further comprise instructions configured to instruct the processor to determine an estimated power consumption for an associated device based upon a power model for the associated device and usage statistics for the associated device.

9. The device of claim 7, wherein the instructions for clustering the population of devices further comprise instructions configured to instruct the processor to:
organize the population of devices based upon energy consumption levels; and
assign each of the populations of devices into one of the plurality of clusters based upon similar energy consumption levels.

10. The device of claim 9, wherein a number of devices assigned to each cluster is determined such that a the estimated total energy consumption for each cluster is approximately equal.

11. The device of claim 7, wherein the instructions for determining a number of samples to measure in each cluster further comprise instructions configured to instruct the processor to perform a counting search to determine the number of samples.

12. The device of claim 7, wherein the instructions for determining the estimated total energy consumption for each cluster further comprise instructions configured to instruct the processor to:
determine a mean energy consumption for each cluster; and
multiply the mean energy consumption for each cluster by the number of power consuming devices in that cluster.

13. A method comprising:
determining, by a processing device, an energy consumption level for each multi-function printing device in a population of multi-function printing devices based upon the power model for an associated multi-function printing device and usage statistics for the associated multi-function printing device;
clustering, by the processing device, the population of power-consuming devices into a plurality of clusters such that each of the plurality of clusters has a similar overall energy consumption;
determining, by the processing device, an estimated total energy consumption for each cluster;
determining, by the processing device, an estimated total energy consumed by the population of multi-function printing devices based upon the total energy consumption for each cluster, wherein the estimated total energy consumed by the population is within an acceptable uncertainty; and
determining, by the processing device, a number of samples to measure in each cluster such that the uncertainty associated with the estimated total energy consumed by the population of multi-function printing devices is minimized.

14. The method of claim 13, wherein clustering the population of devices further comprises:
organizing the population of devices based upon energy consumption levels; and
assigning each of the populations of devices into one of the plurality of clusters based upon similar energy consumption levels.

15. The method of claim 14, wherein a number of devices assigned to each cluster is determined such that a the estimated total energy consumption for each cluster is approximately equal.

16. The method of claim 13, wherein determining a number of samples to measure in each cluster comprises performing a counting search to determine the number of samples.

17. The method of claim 13, wherein determining the estimated total energy consumption for each cluster comprises:
determining a mean energy consumption for each cluster; and
multiplying the mean energy consumption for each cluster by the number of multi-function printing devices in that cluster.
